(19) United States
(12) Patent Application Publication
(10) Pub. No.: US 2025/0129476 A1
(43) Pub. Date: Apr. 24, 2025

(54) OPTICALLY ACTIVE SHOWERHEAD FOR PROCESS CHAMBER

(71) Applicant: Applied Materials, Inc., Santa Clara, CA (US)

(72) Inventors: Tetsuya ISHIKAWA, San Jose, CA (US); Amir H. TAVAKOLI, San Jose, CA (US); Ala MORADIAN, Sunnyvale, CA (US)

(21) Appl. No.: 18/771,367

(22) Filed: Jul. 12, 2024

Related U.S. Application Data
(60) Provisional application No. 63/591,926, filed on Oct. 20, 2023.

(51) Int. Cl. C23C 16/455

(52) U.S. Cl. CPC C23C 16/45565

(57) ABSTRACT

A showerhead for a process chamber is provided including: a first portion that includes a plurality of gas inlets and a first plurality of gas outlets; and a second portion over the first portion, the second portion including a second plurality of gas outlets, wherein the plurality of gas inlets of the first portion are fluidly coupled to the second plurality of gas outlets of the second portion, the first plurality of gas outlets of the first portion are fluidly coupled to the plurality of gas inlets of the first portion, the second portion is transparent to infrared radiation and ultraviolet radiation, and the first portion is transparent to infrared radiation and opaque to ultraviolet radiation.

### CROSS-REFERENCE TO RELATED APPLICATIONS

This application claims benefit of U.S. provisional patent application Ser. No. 63/591,926, filed Oct. 20, 2023, which is hereby incorporated herein by reference.

### BACKGROUND

### Field

Embodiments of the present disclosure generally relate to improved showerheads for supplying gases to process chambers, such as semiconductor process chambers.

### Description of the Related Art

Gases can be provided to the interior volume of a process chamber to perform a process, such as a deposition on a substrate (e.g., a semiconductor substrate) positioned in the process chamber. Controlling the concentration of gases over the substrate during the process is important for achieving the intended process results, such as a uniform deposition from the center of the substrate to the edge of the substrate.

Gases are generally either supplied to the interior volume of a process chamber through a sidewall of the chamber or from above the substrate support using a gas distribution device, such as a showerhead. Supplying gas from the side allows for the portion of the process chamber above the substrate support to be available for other equipment, such as lamps for controlling the temperature of the substrate and sensors (e.g., temperature sensors) for monitoring the process, but achieving the intended gas distribution over the substrate can be more challenging when compared to using a showerhead. On the other hand, using a showerhead above the substrate support to supply gas to the interior volume can be helpful for achieving a specific gas distribution over the substrate during a process, but this comes with the cost of making the region above the substrate support less available for other equipment. For example, the showerhead generally extends across an area as large or larger than the substrate being processed making the region occupied by the showerhead unavailable for other equipment like heating lamps and sensors.

Thus, a need exists for a process chamber that can achieve the gas distribution results of a showerhead without the shortcomings discussed above that are associated with using a showerhead.

### SUMMARY

Embodiments of the present disclosure generally relate to equipment and related methods for improving the gas flow to process chambers, such as semiconductor process chambers.

In one embodiment, a showerhead for a process chamber is provided comprising: a first portion including a plurality of gas inlets and a first plurality of gas outlets; and a second portion over the first portion, the second portion including a second plurality of gas outlets, wherein the plurality of gas inlets of the first portion are fluidly coupled to the second plurality of gas outlets of the second portion, the first plurality of gas outlets of the first portion are fluidly coupled to the plurality of gas inlets of the first portion, the second portion is transparent to infrared radiation and ultraviolet radiation, and the first portion is transparent to infrared radiation and opaque to ultraviolet radiation.

In another embodiment, a process chamber is provided comprising: a chamber body disposed around a process volume; a substrate support in the process volume; and a showerhead positioned over the substrate support, the showerhead comprising: a first portion including a plurality of gas inlets and a first plurality of gas outlets; and a second portion over the first portion, the second portion including a second plurality of gas outlets, wherein the plurality of gas inlets of the first portion are fluidly coupled to the second plurality of gas outlets of the second portion, the first plurality of gas outlets of the first portion are fluidly coupled to the plurality of gas inlets of the first portion, the second portion is transparent to infrared radiation and ultraviolet radiation, and the first portion is transparent to infrared radiation and opaque to ultraviolet radiation.

In another embodiment, a method of processing a substrate is provided comprising: positioning a substrate on a substrate support in a process volume of a process chamber during a first time period; supplying a first process gas and a second process gas to the process volume through a showerhead of the process chamber during the first time period; and directing infrared radiation and ultraviolet radiation at the showerhead, wherein the first process gas flows through a portion of the showerhead that receives infrared radiation and ultraviolet radiation, and the second process gas flows through showerhead to the process volume without being exposed to ultraviolet radiation.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a cross-sectional view of a processing system, according to one embodiment.

FIG. 2A is a schematic cross-sectional view of the showerhead and some other components of the processing system of FIG. 1, according to one embodiment.

FIG. 2B is a schematic cross-sectional view of an alternative showerhead and some other components of the processing system of FIG. 1, according to one embodiment.

FIG. 3 is a process flow diagram of a method for processing a substrate in the processing system from FIG. 1, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to improved showerheads for supplying gases to process chambers, such as semiconductor process chambers. The embodiments of showerheads disclosed herein are formed of different materials that enable the showerhead to transmit or absorb different types of radiation, so that particular types of radiation are (1) able to transmit through the entire showerhead, (2) completely blocked, or (3) able to transmit partially through the showerhead before being blocked. For example, one embodiment of the showerheads disclosed herein can allow most infrared radiation to pass entirely through the showerhead, (2) completely block infrared radiation having a wavelength that is read by a temperature sensor (e.g., a pyrometer), and (3) allow ultraviolet (UV) radiation to pass through a portion of the showerhead before being absorbed by another portion. Infrared heating lamps positioned over the showerhead can be energized to heat the gases in the showerhead and the substrate below the showerhead during a process, such as an epitaxial deposition. UV lamps above the showerhead can be energized to activate gases in a UV-transparent portion of the showerhead while other gases can be sent to a portion of the showerhead in which the UV radiation cannot reach, so that these other gases enter the interior volume of the process chamber without being exposed to UV radiation.

Applying UV radiation to only a portion of the showerhead (e.g., an upper portion) can have several benefits. For example, in some embodiments, applying UV radiation to less than all of the process gases can help with controlling the reaction rate of the process gases in the process chamber. In another embodiment, UV radiation is applied to a cleaning gas without exposing the interior volume of the process chamber to UV radiation. In some embodiments there can be components in the process chamber or on the substrate inside the process chamber that can be damaged by exposure to UV radiation. Thus, the showerheads disclosed herein allow exposure of one or more gases in an upper portion of the showerhead to UV radiation so that process benefits can be achieved by the UV activation of the gas(es) while not exposing the substrate or other components below the showerhead to UV radiation that may be damaging.

Although the following disclosure mainly describes uses of improved showerheads in an epitaxial deposition chamber, the benefits of this disclosure can also be applied to any process (e.g., semiconductor process) that uses a showerhead, such as other deposition processes (e.g., chemical vapor depositions) and etching processes. Additionally, although the benefits of the disclosure are mainly described in relation to a showerhead positioned over a substrate support, the benefits of the disclosure can be applied to any gas distribution device including gas distribution devices positioned over the substrate support or gas distribution devices configured to direct gas through a sidewall of a process chamber.

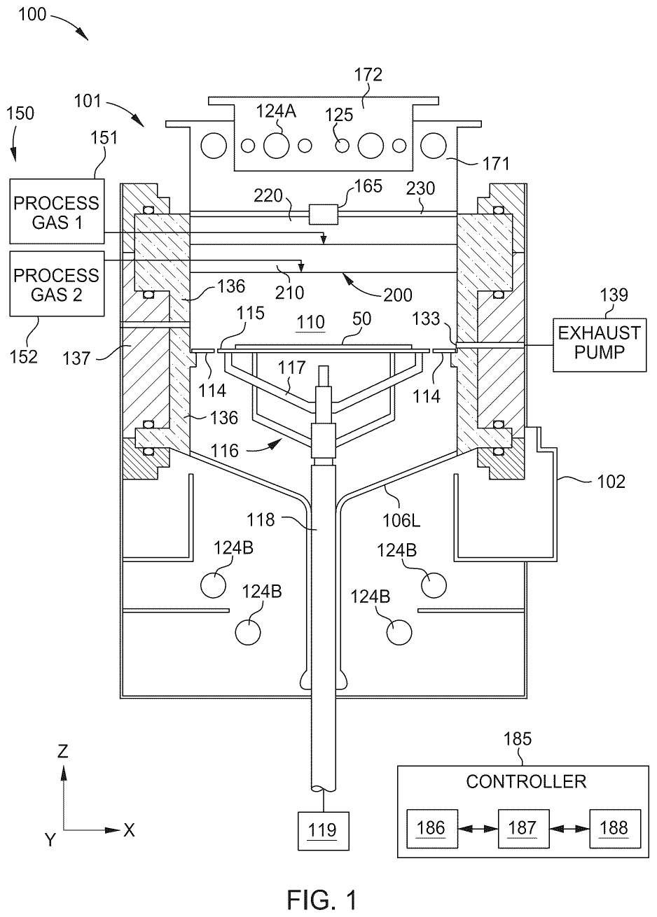

FIG. 1 is a cross-sectional view of a processing system 100, according to one embodiment. The processing system 100 includes a process chamber 101, a gas supply system 150, an exhaust pump 139, and a controller 185. The processing system 100 can be configured to perform epitaxial deposition processes in the process chamber 101 as well as other processes, such as cleaning processes.

The process chamber 101 includes a chamber body 102. In some embodiments, the chamber body 102 can be made of a process resistant material, such as aluminum or stainless steel, for example 316L stainless steel. The chamber body 102 is disposed around structural components of the process chamber 101, such as a showerhead 200, a lower window 106L, an inner liner 136, and an outer liner 137. In one embodiment, the lower window 106L can be formed of quartz. The liners 136, 137 can be positioned between the each of the showerhead 200 and the window 106L and the chamber body 102 to insulate the showerhead 200 and lower window 106L from the chamber body 102. The showerhead 200, the lower window 106L, and the liners 136, 137 enclose an interior volume 110 (also referred to as a process volume) of the process chamber 101.

The process chamber 101 further includes a substrate support assembly 116. The substrate support assembly 116 can include supports 117 and a shaft 118. A susceptor 115 can be positioned on the supports 117. The substrate support assembly 116 can further include an actuator 119 to rotate the shaft 118 and the susceptor 115. The process chamber 101 can further include a preheat ring 114 that can be positioned around the susceptor 115. A substrate 50 can be positioned on the susceptor 115 during processing, such as during an epitaxial deposition.

The gas supply system 150 can include a first process gas source 151 and a second process gas source 152 that can each provide one or more different gases for processes executed in the interior volume 110 of the process chamber 101, such as epitaxial depositions. Although only two process gas sources are shown, the gas supply system 150 can further include gas sources (not shown) for other process gases, cleaning gases, etching gases, purge gases, etc. Gases can be introduced into the interior volume 110 from the gas supply system 150 during depositions, cleaning, etching, or other processes. These gases can be exhausted from the interior volume 110 through an exhaust outlet 133 of the process chamber 101 by the exhaust pump 139.

The process chamber 101 further includes an outer reflector 171 and an inner reflector 172 positioned over the showerhead 200. The outer reflector 171 can be positioned around the inner reflector 172.

The process chamber 101 can further include upper lamps 124A and lower lamps 124B for heating of the substrate 50 and/or the interior volume 110. The upper lamps 124A and the lower lamps 124B can be infrared (IR) lamps. In some embodiments one or more upper lamps 124A can be positioned inside the outer reflector 171 and the inner reflector 172 to direct IR energy towards the susceptor 115 and interior volume 110 through the showerhead 200. Additionally, the lower lamps 124B can be positioned below the lower window 106L to direct IR energy towards the susceptor 115 and interior volume 110 through the lower window 106L.

The process chamber 101 can further include ultraviolet (UV) lamps 125 positioned over the showerhead 200. The ultraviolet lamps 125 can direct UV radiation towards the showerhead 200 to activate one or more process gases, cleaning gases, etching gases or other gases flowing through the showerhead 200 during processing. Activating gases flowing through the showerhead 200 with UV radiation can make the exposed gases more active and/or reactive and thus more likely to complete an intended process in the interior volume 110, such as an epitaxial deposition on the substrate 50 or a cleaning process performed on the substrate or interior chamber components.

The showerhead 200 can be used to uniformly distribute gases, such as process gases from the process gas sources 151, 152, over the substrate 50 and susceptor 115 during processing. As described in further detail below, the showerhead 200 can be formed of two or more different materials to control the type of radiation that is (1) transmitted entirely through the showerhead 200 towards the susceptor 115, (2) transmitted through only a portion of the showerhead 200, or (3) blocked by the showerhead 200.

The showerhead 200 includes a first portion 210, a second portion 220, and a third portion 230. The second portion 220 is formed over the first portion 210. The third portion 230 is formed over the second portion 220. The portions 210, 220, 230 are generally formed of one or more materials that are configured to allow IR radiation to transmit through the portions 210, 220, 230. In one embodiment, the portions 210, 220, 230 are each formed of quartz. In one embodiment, the first portion 210 and the second portion 220 are formed of quartz having a hydroxyl (OH) concentration from about 5 ppm to about 200 ppm, such as from about 10 ppm to about 20 ppm.

The third portion 230 can be configured to filter a particular wavelength range of radiation that is read by a pyrometer 165 as described in further detail below. With the exception of this relatively narrow wavelength range, the third portion 230 is generally transparent to the IR radiation emitted by the upper lamps 124A and the UV lamps 125. In one embodiment, the third portion 230 is formed of quartz having a hydroxyl (OH) concentration from about 500 ppm to about 1200 ppm, such as from about 1050 ppm to about 1150 ppm as these ranges have been observed to block IR radiation from around 1 micron to about 5 micron, such as 2.7 micron.

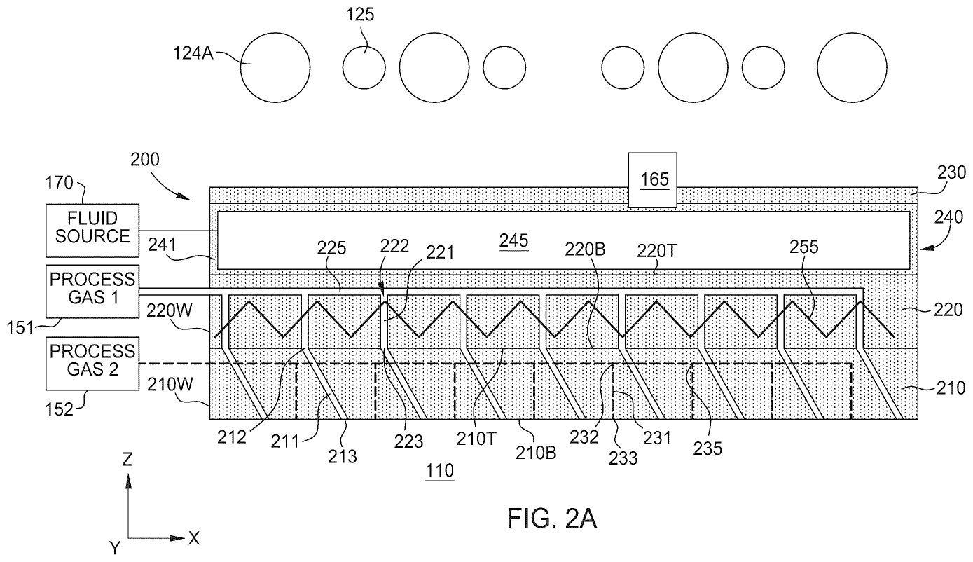

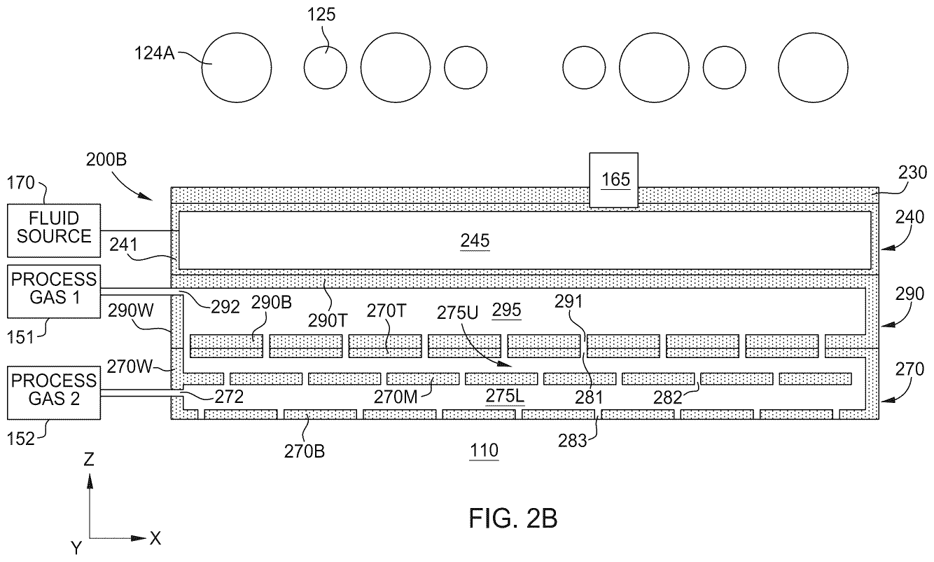

In some embodiments, the portions 210, 220, 230 are each formed of quartz and are each of the portions are diffusion bonded together to form the showerhead 200. A fourth portion 240 (see FIG. 2A) of the showerhead 200 can also be diffusion bonded between the second portion 220 and the third portion 230. The diffusion bonding can be performed at temperatures from about 1000° C. to about 1200° C. as pressure is applied to bond the portions together. In some embodiments, each portion 210, 220, 230, 240 (see FIG. 2A) has a hydroxyl (OH) concentration that decreases in the downward Z-direction within the portion. Furthermore, the first portion 210 can have the lowest hydroxyl concentration of the four portions, the second portion 220 can have the second lowest hydroxyl concentration of the four portions, the fourth portion 240 can have the third lowest hydroxyl concentration of the four portions, and the third portion 230 can have the highest hydroxyl concentration of the four portions. The stepping down of the hydroxyl concentrations in sequence for each portion from the top portion 230 to the bottom portion 210 as well as gradually decreasing the hydroxyl concentration within each portion in the downward Z-direction can assist in promoting the bonds between the different portions in the diffusion bonding process that joins the different portions together because there is less of an abrupt change in hydroxyl concentrations between the contacting surfaces of the different portions.

The process gas from the first process source 151 (also referred to as first process gas) can be supplied initially into the second portion 220 of the showerhead 200. The first process gas then flows from the second portion 220 into the first portion 210 and then to the interior volume 110 that includes the susceptor 115 and substrate 50. The portions 210, 220 each include a plurality of channels described in further detail below that assist in uniformly distributing the first process gas across the interior volume 110 over the substrate 50.

The process gas from the second process source 152 (also referred to as second process gas) can be supplied into the first portion 210 of the showerhead 200. The second process gas then flows through the first portion 210 and into the interior volume 110 that includes the susceptor 115 and substrate 50. The first portion 210 includes a plurality of channels described in further detail below that assist in uniformly distributing the second process gas across the interior volume 110 over the substrate 50.

The first portion 210 and the second portion 220 can each be formed of a material that is transparent to the IR radiation emitted by the upper lamps 124A, so that the IR radiation from the upper lamps 124A can be used to heat the substrate 50 and/or susceptor 115 during processing. Furthermore, the second portion 220 can be transparent to the UV radiation emitted by the UV lamps 125 while the first portion 210 is opaque to the UV radiation emitted by the UV lamps 125. This difference in the radiative properties of the second portion 220 and the first portion 210 can enable the first process gas to be activated by the UV energy from the UV lamps 125 in the second portion 220 of the showerhead 200 while the second process gas that is supplied directly to the first portion 210 is not activated by the UV energy from the lamps 125 due to the UV opaqueness of the first portion 210.

The first portion 210 is configured to transmit IR radiation and absorb UV radiation, so that the gases flowing only through the first portion 210 are exposed to IR radiation without being exposed to UV radiation or to only negligible amounts of UV (e.g., less than 5% or less than 1% of the exposure in the second portion 220 of the showerhead 200). In one embodiment, the first portion 210 is formed from quartz that is doped with a dopant at a sufficient concentration in the quartz to absorb the UV radiation. Some non-limiting examples of dopants that can be used to absorb UV radiation include one or more of zinc, titanium, tin, and cerium. In some of these embodiments, the dopant can have a concentration in the quartz from about 50 ppm to about 10,000 ppm, such as from about 100 ppm to about 5,000 ppm, to absorb the UV radiation.

In another embodiment, the first portion 210 is formed of quartz and is coated with a material that absorbs UV radiation. Some non-limiting examples of materials that can be used to coat the first portion 210 and absorb UV radiation include coating(s) of one or more of silicon oxide, titanium oxide, zinc oxide, tin oxide, and cerium oxide. In one of these embodiments, the first portion 210 can be coated on the top surface, the top and bottom surface, or on the entire outer surface (i.e., side surfaces as well as top and bottom) of the first portion 210 including on the exposed interior surfaces of the channels extending through the first portion 210, such as channels 211, 231 which are described in further detail below.

The process chamber 101 can further include a pyrometer 165 positioned over the showerhead 200 or embedded in the second portion 220 of the showerhead 200. The sensing portion of the pyrometer 165 (e.g., the lower portion in FIG. 1) is not obstructed by the third portion 230. The pyrometer 165 can be configured to monitor a temperature of the substrate 50 during a process, such as an epitaxial deposition, and/or to monitor the temperature of a component, such as the susceptor 115 during a cleaning process. The controller 185 can use the measurements from the pyrometer 165 to monitor and control one or more processes performed by the processing system 100. Although only one pyrometer 165 is shown, some embodiments can include two or more pyrometers, for example to monitor the temperature of the substrate 50 at different radial locations from the center of the substrate 50 to the edge of the substrate 50.

The third portion 230 can be configured to block a band of radiation that the pyrometer 165 is configured to detect. For example, if the pyrometer 165 is configured to detect radiation having a wavelength from around 1.0 micron to about 5.0 micron, then the third portion 230 can be configured to block radiation having a wavelength from around 1.0 micron to about 5.0 micron or a narrower band of radiation. In one embodiment, the third portion 230 can be formed of quartz having a hydroxyl (OH) concentration from about 10 ppm to about 20 ppm.

The processing system 100 also includes the controller 185 for controlling processes performed by the processing system 100. The controller 185 can be any type of controller used in an industrial setting, such as a programmable logic controller (PLC). The controller 185 includes a processor 187, a memory 186, and input/output (I/O) circuits 188. The controller 185 can further include one or more of the following components (not shown), such as one or more power supplies, clocks, communication components (e.g., network interface card), and user interfaces typically found in controllers for semiconductor equipment.

The memory 186 can include non-transitory memory. The non-transitory memory can be used to store the programs and settings described below. The memory 186 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 187 is configured to execute various programs stored in the memory 186, such as epitaxial deposition processes, cleaning, and purging processes. During execution of these programs, the controller 185 can communicate to I/O devices through the I/O circuits 188. For example, during execution of these programs and communication through the I/O circuits 188, the controller 185 can control outputs, such as the position of valves (not shown) to send process gases through the showerhead 200 to the interior volume 110 of the process chamber 101 or to perform cleaning, or purging processes. The memory 186 can further include various operational settings used to control the processing system 100. For example, the settings can include durations for how long processes, such as depositions are executed.

FIG. 2A is a schematic cross-sectional view of the showerhead 200 and some other components of the processing system of FIG. 1, according to one embodiment. The view in FIG. 2A illustrates how the process gases flow through the showerhead 200. Numerous other components, such as walls of the process chamber 101 and reflectors 171, 172 are omitted for clarity.

The first portion 210 includes a top 210T, a bottom 210B, and one or more sides 210W connecting the bottom 210B with the top 210T. Similarly, the second portion 220 includes a top 220T, a bottom 220B, and one or more sidewalls 220W connecting the bottom 220B with the top 220T.

The first process gas from the first process gas source 151 flows along a path through the showerhead 200 by entering the second portion 220 through a main line 225 that connects to a plurality of channels 221 (second plurality of channels). The second plurality of channels 221 connect to another plurality of channels 211 (first plurality of channels) in the first portion 210, which in turn lead to a plurality of outlets 213 that introduce the gas to the interior volume 110.

The first portion 210 of the showerhead 200 includes the first plurality of channels 211 for distributing the first process gas from the first process source 151 to the interior volume 110 over the substrate 50 (see FIG. 1). Each channel 211 of the first plurality of channels 211 extends from the top 210T of the first portion 210 to the bottom 210B of the first portion 210. The bottom 210B of the first portion 210 can also be the bottom of the showerhead 200, so the bottom 210B of the first portion 210 can also be the location where gases are injected into the interior volume 110 of the process chamber 101 from the showerhead 200. Each channel 211 of the first plurality of channels 211 includes an inlet 212 at the top 210T of the first portion 210, where the first process gas is received from the second plurality of channels 221, and an outlet 213 at the bottom 210B of the first portion 210 where the first process gas is injected into the interior volume 110.

The horizontal position of each outlet 213 for each channel 211 can be offset relative to the position of the inlet 212 for that channel 211. For example, in FIG. 2A each outlet 213 is shown having a different X-position relative to the X-position of the inlet 212 for each channel 211. This offsetting of the horizontal position of the outlets 213 relative to the inlets 212 can assist in reducing the amount of UV radiation that can pass through the first portion 210, which is either formed of a material that is opaque to UV radiation or coated with a material configured to block UV radiation, such as titanium oxide or silicon oxide. In one embodiment, the top 210T, the bottom 210B, the sides 210W and the interior of the channels 211 are all coated with a material configured to block UV radiation. In another embodiment (not shown), one or more additional portions that are configured to block UV radiation (e.g., portions coated with a UV-blocking material or formed of a UV-blocking material) can be positioned above the main line 235 described in further detail below to further reduce the likelihood that the second process gas from the second process gas source 152 is exposed to UV radiation.

As discussed above, the second portion 220 of the showerhead 200 can be formed of a material that is transparent to UV radiation, so the staggering of the outlets 213 of the UV-blocking first portion 210 relative to the inlets 212 of the UV-blocking first portion 210 can assist in stopping the UV radiation at locations near the top 210T of the first portion 210. The plurality of channels 211 are shown as diagonal channels for ease of illustration, but the channels could have other designs, such as designs including one or more turns (e.g., 90-degree turns) to further reduce the amount of UV radiation that could pass through one of the channels 211, for example to the interior volume 110.

The second portion 220 of the showerhead 200 includes the second plurality of channels 221 for providing the first process gas to the first plurality of channels 211 in the first portion 210. The main line 225 supplies the first process gas from the first process gas source 151 to each channel 221 of the second plurality of channels 221. Each channel 221 includes an inlet 222 connected with the main line 225. Each channel 221 extends from the inlet 222 to an outlet 223 where the channel 221 is connected with one of the first plurality of channels 211 at the bottom 220B of the second portion 220.

The first portion 210 of the showerhead 200 further includes a third plurality of channels 231 for distributing the second process gas from the second process source 152 to the interior volume 110 over the substrate 50 (see FIG. 1). A main line 235 connects each channel 231 with the second process gas source 152. Each channel 231 includes an inlet 232 connected with the main line 235 and an outlet 233 at the bottom 210B of the first portion 210 where the second process gas is injected into the interior volume 110. The main line 235 and the channels 231 can be spaced apart from the top 210T of the first portion 210 to reduce or prevent UV radiation from interacting with the second process gas in the main line 235 or channels 231. In some embodiments, the second process gas can be routed through the second portion 220 first to provide UV-activation of the second process gas in the second portion 220 of the showerhead 200 as described above for UV-activation of the first process gas in the second portion 220 of the showerhead 200.

In some embodiments, the showerhead 200 can further include a fourth portion 240 located between the second portion 220 and the third portion 230. The fourth portion 240 can include a body 241 and a plenum 245 inside the body 241 that is configured to receive a fluid. In some embodiments, the body 241 can be formed of quartz. In some embodiments, the processing system 100 (see FIG. 1) can further include a fluid source 170. The fluid source 170 can be connected with the plenum 245.

In one embodiment, the fluid source 170 includes a radiation-blocking fluid. For example, in one embodiment the fluid source 170 can include liquid gallium that can be pumped into and evacuated from the plenum 245 to transition from a radiation-blocking mode when gallium is in the plenum 245 and a transparent mode when the liquid gallium has been evacuated from the plenum 245. Liquid gallium is generally opaque to infrared radiation. Thus, supplying liquid gallium to the plenum 245 can block radiation from the lamps 124A and reflectors 171, 172 from radiating towards interior volume 110. In one embodiment, liquid gallium can be provided to the plenum 245 to assist with cooling the substrate 50 (see FIG. 1) in the interior volume 110 more rapidly, for example after a deposition is performed on the substrate 50.

In some embodiments, the plenum 245 can be sized to underlie all of the lamps 124A, 125 as well as overlie all of the susceptor 115 and substrate 50 (see FIG. 1), so that the radiation-blocking fluid (e.g., liquid gallium) blocks substantially all of the infrared radiation above the showerhead 200 from reaching the susceptor 115 and substrate 50. Additionally, in some embodiments, the plenum 245 can be sized to overlie all of the second plurality of channels 221 with the second plurality of channels 221 consisting of all of the channels in the second portion 220 that extend to the bottom 220B of the second portion 220. Sizing the plenum 245 to overlie all of the second plurality of channels 221 can assist in blocking almost all of the IR radiation from above the second portion 220. In other embodiments, the fourth portion 240 and plenum 245 can each have a horizontal size in the XY plane that is larger than the second portion 220, so that providing liquid gallium to the plenum 245 blocks substantially all of the IR radiation from reaching the second portion 220. In reference to FIG. 2B below, the plenum 245 can be configured to overlie all of the plenum 295 of the second portion 290 of the showerhead 200B.

In another embodiment, the fluid source 170 contains a heat transfer fluid, such as a coolant or heating fluid. The heat transfer fluid can be provided to the plenum 245 to raise or lower the temperature of the showerhead 200 and/or substrate 50. For example, in one embodiment the heat transfer fluid is a heating fluid that raises the temperature of the process gases from the process gas sources 151, 152 in the showerhead, so that the process gases are more likely to react upon mixing in the interior volume 110 over the substrate 50, so that the rate of deposition or other process can be increased.

In some embodiments, the showerhead 200 can additionally include a heater 255 (e.g., a resistive heater) located in the second portion 220 or another portion of the showerhead 200. Electrical power can be provided to the heater 255 when an increase in temperature of the showerhead 200 and/or substrate 50 is beneficial to the process being executed. In one embodiment, the heater 255 can be formed of molybdenum or tungsten.

FIG. 2B is a schematic cross-sectional view of an alternative showerhead 200B and some other components of the processing system of FIG. 1, according to one embodiment. The view in FIG. 2B illustrates how the process gases flow through the showerhead 200B. Numerous components, such as the heater 255 in the showerhead, the walls of the process chamber 101 and reflectors 171, 172 are omitted for clarity.

The showerhead 200B is similar to the showerhead 200 described above in reference to FIG. 2A except that the showerhead 200B includes a first portion 270 and a second 290 that are different from the corresponding first portion 210 and second portion 220 included in the showerhead 200.

The first portion 270 of the showerhead 200B can be formed of and/or coated with any of the materials described above for the first portion 210. Thus, the first portion 270 of the showerhead 200B is formed of a material that is transparent to infrared radiation and opaque to UV radiation. Similarly, the second portion 290 of the showerhead 200B can be formed any of the materials described above for the second portion 220. Thus, the second portion 290 of the showerhead 200B is formed of a material that is transparent to infrared radiation and UV radiation.

The first portion 270 includes a top 270T, a bottom 270B, and one or more sides 270W connecting the bottom 270B with the top 270T. The first portion 270 further includes a middle section 270M, an upper plenum 275U formed over the middle section 270M, and a lower plenum 275L formed below the middle section 270M. The first portion 270 further includes a main gas inlet 272 connecting the second gas source 152 with the lower plenum 275L.

The second portion 290 includes a top 290T, a bottom 290B, and one or more sides 290W connecting the bottom 290B with the top 290T. The second portion 290 includes a plenum 295. The second portion 290 further includes a main gas inlet 292 connecting the first gas source 151 with the plenum 295. In some embodiments, the bottom 290B of the second portion 290 can be omitted with the top 270T of the first portion 270 forming the bottom of the plenum 295.

The top 270T of the first portion 270 includes a first plurality of apertures 281 (also referred to as plurality of gas inlets) that fluidly couple the upper plenum 275U with the plenum 295 of the second portion 290. The middle section 270M of the first portion 270 includes a second plurality of apertures 282 that fluidly couple the upper plenum 275U with the lower plenum 275L. The bottom 270B of the first portion 270 includes a third plurality of apertures 283 (also referred to as first plurality of gas outlets) that fluidly couple the lower plenum 275L with the process volume 110 of the process chamber 101.

The first plurality of apertures 281 can be arranged across a first horizontal plane. The second plurality of apertures 282 can be arranged across a second horizontal plane. The third plurality of apertures 283 can be arranged across a third horizontal plane. The horizontal position of the third plurality of apertures 283 can be offset relative to the horizontal position of the first plurality of apertures 281 and offset relative to the horizontal position of the second plurality of apertures 282. Similarly, horizontal position of the second plurality of apertures 282 can be offset relative to the horizontal position of the first plurality of apertures 281. The staggering of the horizontal positions of the apertures 281-283 relative to each other can help prevent or substantially reduce the amount of UV radiation that can reach the lower plenum 275L or interior volume 110 of the process chamber as radiation propagating along any straight line path is blocked by the UV-blocking material of the top 270T, middle section 270M, or bottom 270B of the first portion 270.

The bottom 290B of the second portion 290 includes a plurality of apertures 291 (also referred to as second plurality of gas outlets) that fluidly couple the plenum 295 of the second portion 290 with the upper plenum 275U of the first portion 270.

The first process gas from the first process gas source 151 flows along a path through the showerhead 200B by entering the plenum 295 of the second portion 290 through the main inlet 292. The first process gas then flows into the upper plenum 275U of the first portion 270 by flowing out of the plenum 295 through the plurality of apertures 291 and into the upper plenum 275U through the first plurality of apertures 281. The first process gas then flows into the lower plenum 275L of the first portion 270 by flowing out of the upper plenum 275U through the second plurality of apertures 282. The first process gas then flows into the process volume 110 of the process chamber 101 from the lower plenum 275L by flowing through the third plurality of apertures 283. The first process gas can mix with the second process gas in the lower plenum 275.

The second process gas from the second process gas source 152 flows along a path through the showerhead 200B by entering the lower plenum 275L of the first portion 270 through the main inlet 272. The second process gas then mixes with the first process gas in the lower plenum 275L of the first portion 270. The mixture of the first process gas and the second process gas then flows out of the lower plenum 275L to the process volume 110 through the third plurality of apertures 283. The UV-blocking material of the first portion 270 prevents or substantially reduces the amount of UV radiation that the second process gas is exposed to in the lower plenum 275 as the top 270T and the middle section 270M can block UV radiation.

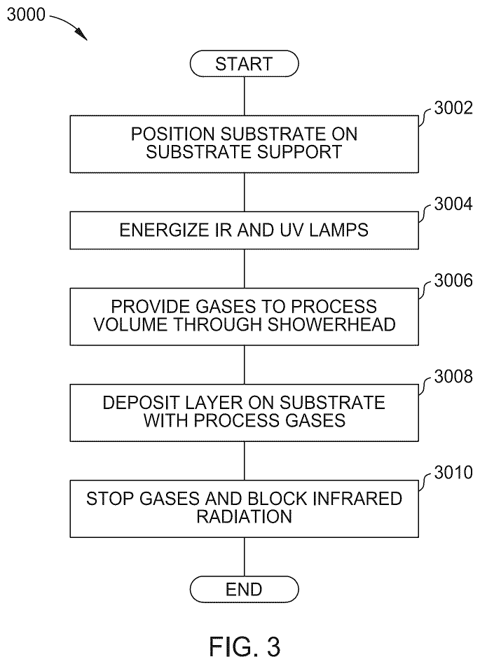

FIG. 3 is a process flow diagram of a method 3000 for processing a substrate 50 in the processing system 100 from FIG. 1, according to one embodiment. The method 3000 is described in reference to FIGS. 1, 2A, 2B, and 3. The method 3000 can be executed by the controller 185. The method 3000 can be executed using the showerhead 200 of FIG. 2A or the showerhead 200B of FIG. 2B.

The method begins at block 3002. At block 3002, a substrate is positioned on the susceptor 115 in the interior volume 110 of the process chamber 101 during a first time period.

At block 3004, the upper lamps 124A, the lower lamps 124B, and the UV lamps 125 are energized during the first time period. The upper lamps 124A direct infrared radiation at the corresponding showerhead 200, 200B. Similarly, the UV lamps 125 direct UV radiation at the corresponding showerhead 200, 200B. The second portion 220, 290 of each corresponding showerhead 200, 200B is formed of a material that is transparent to infrared radiation and ultraviolet radiation. Conversely, the first portion 210, 270 of each corresponding showerhead 200, 200B is transparent to infrared radiation but is formed of a material or includes a material (e.g., a coating) that is opaque to UV radiation.

At block 3006, a first process gas from the first process gas source 151 and a second process gas from the second process gas source 152 are supplied to the interior volume 110 of the process chamber 101 through the corresponding showerhead 200, 200B during the first time period. The first process gas flows along a path through the first portion 210, 270 and the second portion 220, 290 of the corresponding showerhead 200, 200B. Thus, the first process gas is exposed to both infrared radiation and UV radiation in the first portion 210, 270 of the corresponding showerhead 200, 200B. Conversely, the second process gas flows along a path that only goes through the first portion 210, 270 without going through the second portion 220, 290 of the corresponding showerhead 200, 200B. Thus, the second process gas is only exposed to infrared radiation in the first portion 210, 270 without being exposed to UV radiation in the corresponding showerhead 200, 200B.

At block 3008, a first layer is deposited on the substrate with the first process gas and the second process gas in the interior volume 110 of the process chamber 101 during the first time period.

At block 3010, the flow of the first process gas and the second process gas are stopped, and the plenum 245 is filled with an infrared radiation-blocking fluid, such as gallium, to block radiation from above the fourth portion 240 of the corresponding showerhead 200, 200B from continuing to heat the process volume 110 and substrate 50. Filling the plenum 245 with an infrared radiation-blocking fluid can allow for the substrate 50 to cool more quickly.

While the foregoing is directed to embodiments of the present disclosure, other and further embodiments of the disclosure may be devised without departing from the basic scope thereof.

What is claimed is:

1. A showerhead for a process chamber comprising:
a first portion including a plurality of gas inlets and a first plurality of gas outlets; and
a second portion over the first portion, the second portion including a second plurality of gas outlets, wherein
the plurality of gas inlets of the first portion are fluidly coupled to the second plurality of gas outlets of the second portion,
the first plurality of gas outlets of the first portion are fluidly coupled to the plurality of gas inlets of the first portion,
the second portion is transparent to infrared radiation and ultraviolet radiation, and
the first portion is transparent to infrared radiation and opaque to ultraviolet radiation.

2. The showerhead of claim 1, wherein the first portion and the second portion are each formed of quartz.

3. The showerhead of claim 2, wherein the first portion is coated with one or more of titanium oxide, silicon oxide, zinc oxide, tin oxide, or cerium oxide.

4. The showerhead of claim 2, wherein an OH content of the quartz in the second portion is from about 10 ppm to about 200 ppm.

5. The showerhead of claim 2, wherein the first portion is doped with one or more of zinc, titanium, tin, or cerium at a concentration from about 100 ppm to about 50,000 ppm.

6. The showerhead of claim 1, further comprising a third portion over the second portion, wherein the third portion is connected to the second portion and the third portion is configured to filter radiation having a wavelength from about 1 micron to about 5 micron.

7. The showerhead of claim 6, wherein the third portion is formed of quartz having an OH content from about 500 ppm to about 1200 ppm.

8. The showerhead of claim 1, wherein
the plurality of gas inlets of the first portion are arranged across a first horizontal plane,
the first plurality of gas outlets of the first portion are arranged across a second horizontal plane, and
a horizontal position of the gas inlets of the first portion are offset from a horizontal position of the first plurality of gas outlets of the first portion.

9. The showerhead of claim 1, further comprising a fourth portion formed over the second portion, wherein
the fourth portion is connected to the second portion,
the second plurality of gas outlets consists of all of the gas outlets in the second portion that are fluidly coupled to the first portion, and
the fourth portion includes a plenum that overlies all of the second plurality of gas outlets.

10. A process chamber comprising:
a chamber body disposed around a process volume;
a substrate support in the process volume; and
a showerhead positioned over the substrate support, the showerhead comprising:
a first portion including a plurality of gas inlets and a first plurality of gas outlets; and
a second portion over the first portion, the second portion including a second plurality of gas outlets, wherein
the plurality of gas inlets of the first portion are fluidly coupled to the second plurality of gas outlets of the second portion,
the first plurality of gas outlets of the first portion are fluidly coupled to the plurality of gas inlets of the first portion,
the second portion is transparent to infrared radiation and ultraviolet radiation, and
the first portion is transparent to infrared radiation and opaque to ultraviolet radiation.

11. The process chamber of claim 10, wherein the first portion and the second portion of the showerhead are each formed of quartz.

12. The process chamber of claim 11, wherein the first portion is coated with one or more of titanium oxide, silicon oxide, zinc oxide, tin oxide, or cerium oxide.

13. The process chamber of claim 11, wherein an OH content of the quartz in the second portion is from about 10 ppm to about 200 ppm.

14. The process chamber of claim 10, wherein the first portion is doped with one or more of zinc, titanium, tin, or cerium at a concentration from about 100 ppm to about 50,000 ppm.

15. The process chamber of claim 10, further comprising a pyrometer positioned over the first portion of the showerhead, wherein the showerhead further comprises a third portion over the second portion, wherein
the third portion is connected to the second portion and the third portion is configured to filter radiation having a wavelength from about 1 micron to about 5 micron, and
the pyrometer is configured to perform measurements by detecting radiation having a wavelength from about 1 micron to about 5 micron.

16. The process chamber of claim 15, wherein the third portion is formed of quartz having an OH content from about 500 ppm to about 1200 ppm.

17. The process chamber of claim 10, wherein
the plurality of gas inlets of the first portion are arranged across a first horizontal plane,
the first plurality of gas outlets of the first portion are arranged across a second horizontal plane, and
a horizontal position of the gas inlets of the first portion are offset from a horizontal position of the first plurality of gas outlets of the first portion.

18. The process chamber of claim 10, wherein
the showerhead further comprises a fourth portion over the second portion,
the fourth portion is connected to the second portion,
the second plurality of gas outlets consists of all of the gas outlets in the second portion that are fluidly coupled to the first portion, and
the fourth portion includes a plenum that overlies all of the second plurality of gas outlets.

19. A method of processing a substrate comprising:
positioning a substrate on a substrate support in a process volume of a process chamber during a first time period;
supplying a first process gas and a second process gas to the process volume through a showerhead of the process chamber during the first time period; and
directing infrared radiation and ultraviolet radiation at the showerhead, wherein
the first process gas flows through a portion of the showerhead that receives infrared radiation and ultraviolet radiation, and
the second process gas flows through showerhead to the process volume without being exposed to ultraviolet radiation.

20. The method of claim 19, further comprising supplying an infrared-blocking fluid to a plenum of the showerhead during a second time period after the first time period when the substrate is on the substrate support.
